(19) United States
(12) Patent Application Publication
(10) Pub. No.: US 2025/0391792 A1
(43) Pub. Date: Dec. 25, 2025

(54) HYBRID BONDED CAPACITOR DEVICE STRUCTURE

(71) Applicant: International Business Machines Corporation, Armonk, NY (US)

(72) Inventors: Nicholas Alexander Polomoff, Hopewell Junction, NY (US); Moitreyee Mukherjee-Roy, San Jose, CA (US)

(21) Appl. No.: 18/753,054

(22) Filed: Jun. 25, 2024

(51) Int. Cl. H01L 23/64; H01L 23/00; H01L 23/522; H01L 23/528; H01L 25/16

(52) U.S. Cl. CPC H01L 23/642; H01L 23/5223; H01L 23/5226; H01L 23/5283; H01L 24/08; H01L 25/16; H01L 2224/0801; H01L 2224/08146; H01L 2924/1205

(57) ABSTRACT

A device comprises a first semiconductor structure disposed on a second semiconductor structure, and a capacitor structure disposed at an interface portion of the first semiconductor structure and the second semiconductor structure. The capacitor structure comprises a first conductive plate, at least one dielectric layer inlayed within the first conductive plate and at least a second conductive plate inlayed within the first conductive plate.

### BACKGROUND

Innovations in semiconductor fabrication and packaging technologies have enabled the development of smaller scale, higher density semiconductor integrated circuit (IC) chips, as well as the development of highly integrated chip modules with wiring and area array input/output (I/O) contact densities that enable dense packaging of IC chips. For certain applications, high-performance electronic devices are constructed by fabricating semiconductor devices on separate wafers and bonding the wafers together to construct an integrated semiconductor device package.

### SUMMARY

Embodiments of the disclosure include hybrid bonded structures and techniques for forming hybrid bonded capacitor devices with inlayed capacitor elements.

In one embodiment, a device includes a first semiconductor structure disposed on a second semiconductor structure, and a capacitor structure disposed at an interface portion of the first semiconductor structure and the second semiconductor structure. The capacitor structure comprises a first conductive plate, at least one dielectric layer inlayed within the first conductive plate and at least a second conductive plate inlayed within the first conductive plate.

In another embodiment, a device includes a first semiconductor structure disposed on a second semiconductor structure, and a capacitor structure comprising a first conductive plate, at least one dielectric layer surrounded by the first conductive plate and at least a second conductive plate surrounded by the first conductive plate and the at least one dielectric layer. The capacitor structure is disposed in the first semiconductor structure and in the second semiconductor structure.

In another embodiment, a device includes a first semiconductor structure disposed on top of and facing a second semiconductor structure, and a capacitor structure disposed in the first semiconductor structure and in the second semiconductor structure. The capacitor structure comprises a first conductive plate disposed around at least one dielectric layer and around at least a second conductive plate, wherein the at least one dielectric layer is disposed around the second conductive plate.

These and other features and advantages of embodiments described herein will become more apparent from the accompanying drawings and the following detailed description.

### BRIEF DESCRIPTION OF THE DRAWINGS

FIGS. 1A and 1B depict three-dimensional views of first and second semiconductor structures for hybrid bonding, each semiconductor structure including a capacitor structure, according to an embodiment of the invention.

FIGS. 2 and 3 depict cross-sectional views of the first and second semiconductor structures following patterning and removal of portions of hybrid bonding level dielectric layers to form openings for a capacitor region, according to an embodiment of the invention.

FIGS. 4 and 5 depict cross-sectional views of the first and second semiconductor structures following deposition of capacitor dielectric material, according to an embodiment of the invention.

FIGS. 6 and 7 depict cross-sectional views of the first and second semiconductor structures following planarization of the capacitor dielectric material, according to an embodiment of the invention.

FIGS. 8 and 9 depict cross-sectional views of the first and second semiconductor structures following additional pattering of the capacitor region and metal liner layer deposition, according to an embodiment of the invention.

FIGS. 10 and 11 depict cross-sectional views of the first and second semiconductor structures following metal fill layer deposition, according to an embodiment of the invention.

FIGS. 12 and 13 depict cross-sectional views of the first and second semiconductor structures following planarization of the metal liner and metal fill layers, according to an embodiment of the invention.

FIG. 14 depicts a cross-sectional view of the first and second semiconductor structures following flipping of the first semiconductor structure onto the second semiconductor structure, and aligning of the first semiconductor structure with the second semiconductor structure, according to an embodiment of the invention.

FIG. 15 depicts a cross-sectional view of heat treatment of the first and second semiconductor structures to cause hybrid bonding of the first and second semiconductor structures, according to an embodiment of the invention.

FIG. 16 depicts a cross-sectional view of the hybrid bonded first and second semiconductor structures, according to an embodiment of the invention.

FIG. 17 depicts a three-dimensional view of the hybrid bonded structure of FIG. 16, according to an embodiment of the invention.

FIGS. 18 and 19 depict cross-sectional views of first and second semiconductor structures following patterning and removal of portions of hybrid bonding level dielectric layers to form openings for a capacitor region, according to an additional embodiment of the invention.

FIGS. 20 and 21 depict cross-sectional views of the first and second semiconductor structures following deposition of capacitor dielectric material, according to an additional embodiment of the invention.

FIGS. 22 and 23 depict cross-sectional views of the first and second semiconductor structures following planarization of the capacitor dielectric material, according to an additional embodiment of the invention.

FIGS. 24 and 25 depict cross-sectional views of the first and second semiconductor structures following additional pattering of the capacitor region and metal liner layer deposition, according to an additional embodiment of the invention.

FIGS. 26 and 27 depict cross-sectional views of the first and second semiconductor structures following metal fill layer deposition, according to an additional embodiment of the invention.

FIGS. 28 and 29 depict cross-sectional views of the first and second semiconductor structures following planarization of the metal liner and metal fill layers, according to an additional embodiment of the invention.

FIG. 30 depicts a cross-sectional view of the first and second semiconductor structures following flipping of the first semiconductor structure onto the second semiconductor structure, and aligning of the first semiconductor structure with the second semiconductor structure, according to an additional embodiment of the invention.

FIG. 31 depicts a cross-sectional view of heat treatment of the first and second semiconductor structures to cause hybrid bonding of the first and second semiconductor structures, according to an additional embodiment of the invention.

FIG. 32 depicts a cross-sectional view of the hybrid bonded first and second semiconductor structures, according to an additional embodiment of the invention.

FIGS. 33, 34 and 35 depict three-dimensional views of the hybrid bonded structure of FIG. 32, according to an additional embodiment of the invention.

FIGS. 36A, 36B and 36C depict three-dimensional views of first and second semiconductor structures for hybrid bonding, each semiconductor structure including a capacitor structure, according to another embodiment of the invention.

### DETAILED DESCRIPTION

Embodiments of the disclosure will now be discussed in further detail with regard to structures and techniques for forming hybrid bonded capacitor devices with inlayed capacitor elements. It is to be understood that the various layers, structures, and regions shown in the accompanying drawings are schematic illustrations that are not drawn to scale. In addition, for case of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the drawings to denote the same or similar features, elements, or structures, and thus, a detailed explanation of the same or similar features, elements, or structures will not be repeated for each of the drawings.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount. The term “exemplary” as used herein means “serving as an example, instance, or illustration.” Any embodiment or design described herein as “exemplary” is not to be construed as preferred or advantageous over other embodiments or designs. The word “over” as used herein to describe forming a feature (e.g., a layer) “over” a side or surface, means that the feature (e.g., the layer) may be formed “directly on” (i.e., in direct contact with) the implied side or surface, or that the feature (e.g., the layer) may be formed “indirectly on” the implied side or surface with one or more additional layers disposed between the feature (e.g., the layer) and the implied side or surface.

Further, the term “semiconductor die” or “die” as used herein refers to a block of semiconductor material on which a given functional circuit (e.g., memory circuit, processor circuitry, etc.) and metallization levels (e.g., front-end-of-line (FEOL), middle-of-line (MOL), back-end-of-line (BEOL) metallization levels) are fabricated. Similarly, a semiconductor structure may also refer to a block of semiconductor material on which a given functional circuit and metallization levels are fabricated.

As used herein, “high-K” refers to dielectric materials having a relative dielectric constant greater than 7.

As used herein, “low-K” refers to dielectric materials having a relative dielectric constant less than 7, and includes ultra-low-k dielectric materials.

As used herein, “hybrid bonding” refers to a 3D packing technique to connect semiconductor structures. Hybrid bonding forms connections of semiconductor structures through metal pads which are embedded in a dielectric layer at a bond interface on each semiconductor structure that is being bonded. Fusion bonding forms connections of semiconductor structures via dielectric layers at a bond interface on each semiconductor structure being bonded.

Various conventional techniques, such as two-dimensional (2-D) packaging and three-dimensional (3-D) packaging techniques, can be utilized to construct a semiconductor device package structure. With 2-D packaging, package structures can be constructed by connecting multiple semiconductor IC dies directly to a package substrate using direct chip attachment (DCA) techniques (e.g., flip-chip bonding), wherein the semiconductor IC chips are mounted in the package laterally adjacent to each other (e.g., in a single plane, or coplanar to each other). In this regard, 2-D packaging techniques can require a relatively large package footprint to accommodate multiple semiconductor IC chips. In addition, the I/O communication paths between adjacent chips can be very long since chip-to-chip I/O communication is made through chip-substrate-chip connections and interfaces, which can result in noisy and long interconnect lengths, which can degrade signal integrity.

On the other hand, with 3-D packaging, two more semiconductor IC chips are vertically stacked on top of each other, and interconnected (without an intermediate layer or package substrate) using vertical interconnection structures such as through silicon via (TSV) interconnect structures. While 3-D packaging can provide improvement in communication bandwidth between the stacked chips, there are various problematic issues associated with 3-D packaging.

For example, some issues associated with current 3-D packaging approaches include, but are not limited to: (i) reliability issues of bonded structures; (ii) increased noise from power supplies at high frequency due to high speed circuit switching; (iii) decreased stack assembly yield, requiring more chip real estate for yield loss mitigation through, for example, redundancy; (iv) large areas for capacitor structures; (v) requirements for extra chip processing such as backside thinning to keep the stacked chips as thin as possible as well as extra fabrication specific steps for TSVs; (vi) chip stacking limits, etc.

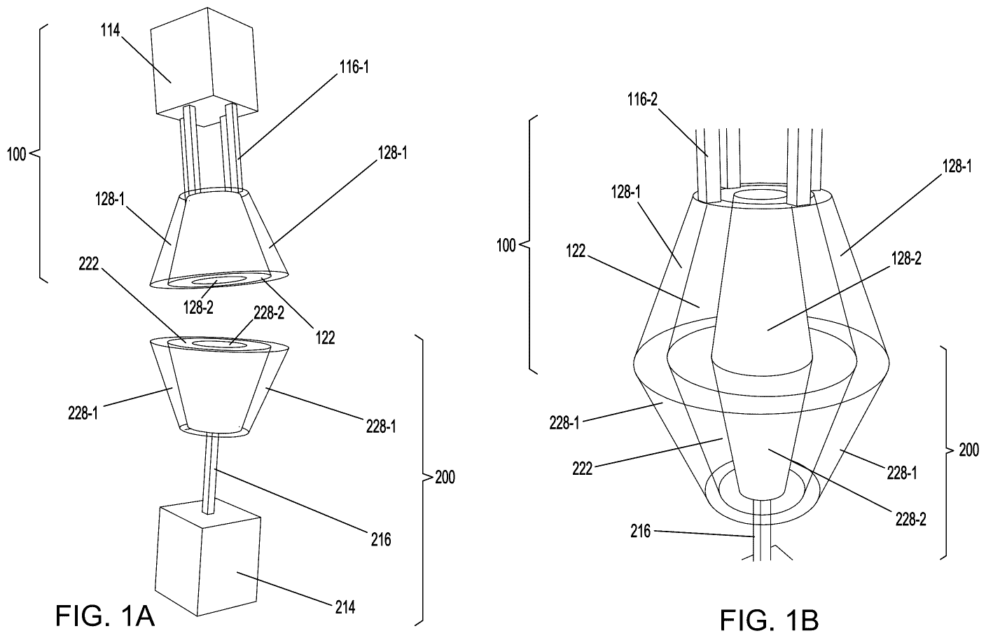

Referring to FIGS. 1A and 1B, a first semiconductor structure 100 and a second semiconductor structure 200 are each manufactured to include parts of a capacitor structure, each part comprising an outer conductive plate portion, a dielectric layer and an inner conductive plate portion. When the first semiconductor structure 100 is hybrid bonded to the second semiconductor structure 200, an integrated capacitor structure is formed comprising an integrated outer conductive plate, an integrated dielectric layer and an integrated inner conductive plate. The integrated capacitor structure is disposed in the first and second semiconductor structures 100 and 200 and at an interface portion between the first and second semiconductor structures 100 and 200.

In more detail, a first part of the capacitor structure forming part of a first semiconductor structure 100 includes a first outer conductive plate portion 128-1, a first dielectric layer 122 and a first inner conductive plate portion 128-2. Similarly, a second part of the capacitor structure forming part of the second semiconductor structure 200 includes a second outer conductive plate portion 228-1, a second dielectric layer 222 and a second inner conductive plate portion 228-2 configured to be aligned with the first outer conductive plate portion 128-1, first dielectric layer 122 and first inner conductive plate portion 128-2 when hybrid bonding is performed.

In FIGS. 1A and 1B, the parts of the capacitor structure of the first and second semiconductor structures 100 and 200 have a circular shape, where the first and second outer conductive plate portions 128-1 and 228-1 are respectively formed around (e.g., surround) the first and second dielectric layers 122 and 222, which are respectively formed around (e.g., surround) the first and second inner conductive plate portions 128-2 and 228-2. The first outer conductive plate portion 128-1, the first dielectric layer 122, and the first inner conductive plate portion 128-2 are concentric, and the second outer conductive plate portion 228-1, the second dielectric layer 222, and the second inner conductive plate portion 228-2 are concentric. The first inner conductive plate portion 128-2 is inlayed within the first dielectric layer 122 and within the first outer conductive plate portion 128-1, and the first dielectric layer 122 is inlayed within the first outer conductive plate portion 128-1. Similarly, the second inner conductive plate portion 228-2 is inlayed within the second dielectric layer 222 and within the second outer conductive plate portion 228-1, and the second dielectric layer 222 is inlayed within the second outer conductive plate portion 228-1. As can be understood, in illustrative embodiments, the first and second outer conductive plate portions 128-1 and 228-1 each have a hollow central portion in which the first and second dielectric layers 122 and 222 are respectively formed, and in which the first and second inner conductive plate portions 128-2 and 228-2 are respectively formed. As an alternative to being circular, the parts of the capacitor structure of the first and second semiconductor structures 100 and 200 can have an oval shape.

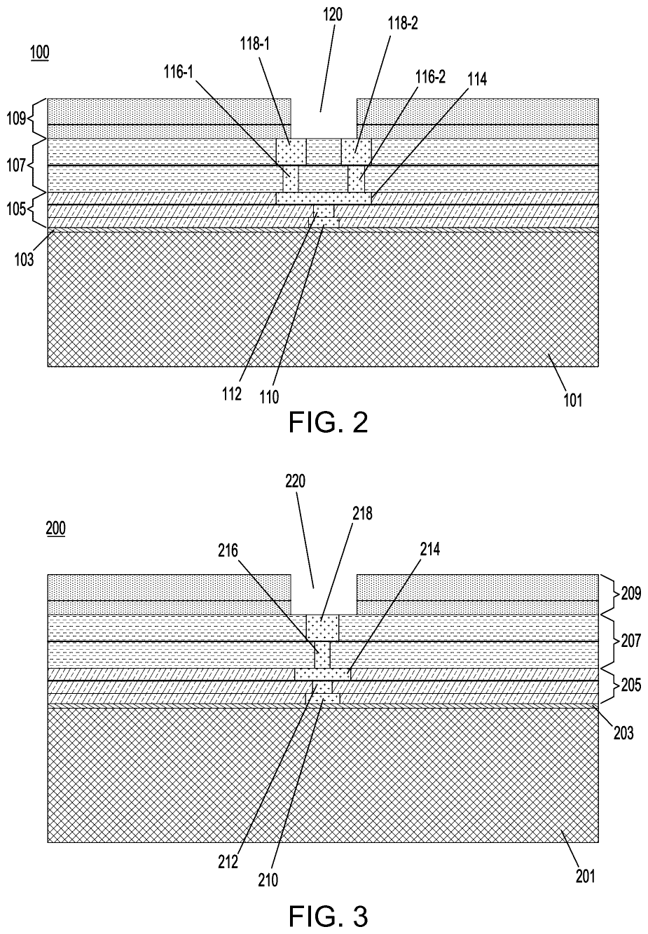

Referring to FIGS. 2 and 3, the first semiconductor structure 100 (or “first semiconductor die”) and the second semiconductor structure 200 (or “second semiconductor die”) include a first semiconductor substrate 101 and a second semiconductor substrate 201, respectively. A first semiconductor substrate 101 and a second semiconductor substrate 201 include semiconductor materials including, but not limited to, silicon, III-V, II-V compound semiconductor materials or other like semiconductor materials. In addition, multiple layers of the semiconductor materials can be used as the semiconductor material of the first and second semiconductor substrates 101 and 201. Respective first and second base dielectric hermetic layers 103 and 203 are formed on the first and second semiconductor substrates 101 and 201. The first and second base dielectric hermetic layers 103 and 203 comprise, for example, silicon nitride (SIN) layers that are disposed on top of the first and second semiconductor substrates 101 and 201 before processing.

The first and second semiconductor structures 100 and 200 each include a first dielectric layer stack 105/205, a second dielectric layer stack 107/207 on the first dielectric layer stack 105/205 and a third dielectric layer stack 109/209 on the second dielectric layer stack 107/207. In illustrative embodiments, the first, second and third dielectric layer stacks 105/205, 107/207 and 109/209 include, but are not necessarily limited to, various combinations of tetraethyl orthosilicate (TEOS), silicon dioxide (SiO₂), carbon-doped silicon oxide (SiCOH), SILK® dielectrics, and/or porous forms of these low-k dielectric films. The first, second and third dielectric layer stacks 105/205, 107/207 and 109/209 include multiple layers of the same or different materials deposited in multiple deposition steps depending on the design and fabrication processes associated with the first and second semiconductor structures 100 and 200. In some embodiments, the first, second and third dielectric layer stacks 105/205, 107/207 and 109/209 may include the same dielectric materials or different numbers of layers than what is shown. As can be understood by one of ordinary skill in the art, the first dielectric layer stacks 105 and 205 can be on the first and second semiconductor substrates 101 and 201, respectively, with intervening layers (e.g., lower conductive lines, devices, etc.) between the first and second dielectric layer stacks 105 and 205, and the first and second semiconductor substrates 101 and 201. A plurality of devices can be on or within the first and second semiconductor substrates 101 and 201, such as, for example, transistors, capacitors, and resistors. For example, in illustrative embodiments, there are additional wiring levels and structures along with devices (e.g., transistors) within the first and second dielectric layer stacks 105 and 205 and connecting to devices that are built into the first and second semiconductor substrates 101 and 201 through the first and second base dielectric hermetic layers 103 and 203.

The first semiconductor structure 100 includes a first metallization level M1 including a first level contact 110, a second metallization level M2 including a second level contact 114, and a third metallization level M3 including two third level contacts 118-1 and 118-2. A first via 112 connects the first level contact 110 and the second level contact 114. Respective second vias 116-1 and 116-2 (collectively “second vias 116”) connect the two third level contacts 118-1 and 118-2 (collectively “third level contacts 118”) to the second level contact 114. The first level contact 110, first via 112 and second level contact 114 are formed in the first dielectric layer stack 105. The two third level contacts 118-1 and 118-2 and second vias 116-1 and 116-2 are formed in the second dielectric layer stack 107.

The second semiconductor structure 200 includes another first metallization level M1′ including an additional first level contact 210, another second metallization level M2′ including an additional second level contact 214, and another third metallization level M3′ including an additional third level contact 218. An additional first via 212 connects the additional first level contact 210 and the additional second level contact 214. An additional second via 216 connects the additional third level contacts 218 to the additional second level contact 214. The additional first level contact 210, additional first via 212 and additional second level contact 214 are formed in the first dielectric layer stack 205. The additional third level contact 218 and the additional second via 216 are formed in the second dielectric layer stack 207.

The metallization levels M1, M1′, M2, M2′, M3 and M3′ can include, for example, wiring that is present on a chip, including, for example, multiple metal levels corresponding to circuit wiring, bussing, power distribution, input-output (I/O), backside power rails or other voltage or signal sources, etc.

In illustrative embodiments, the contacts 110, 114, 118-1, 118-2, 210, 214 and 218, and the vias 112, 116-1, 116-2, 212 and 216 include, for example, a silicide layer, such as a silicide formed with Ni, Ti, NiPt, etc., a metal adhesion layer, such as TiN, and a conductive metal fill layer, such as Cu, W, Al, Co, Ru, etc., and can be deposited using, for example, a deposition technique such as chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), sputtering and/or plating, followed by a planarization process such as, chemical mechanical planarization (CMP) to remove excess portions of the metal material from on top of dielectric layers.

Photoresists (not shown) are patterned to create openings corresponding to where parts of capacitor structures are to be formed. The openings in the photoresists expose portions of the third dielectric layer stacks 109/209 that are etched to create first and second openings 120 and 220 respectively exposing portions of the two third level contacts 118-1 and 118-2 of the first semiconductor structure 100 and the additional third level contact 218 of the second semiconductor structure 200. The etch can be performed using a reactive ion etching (RIE) process.

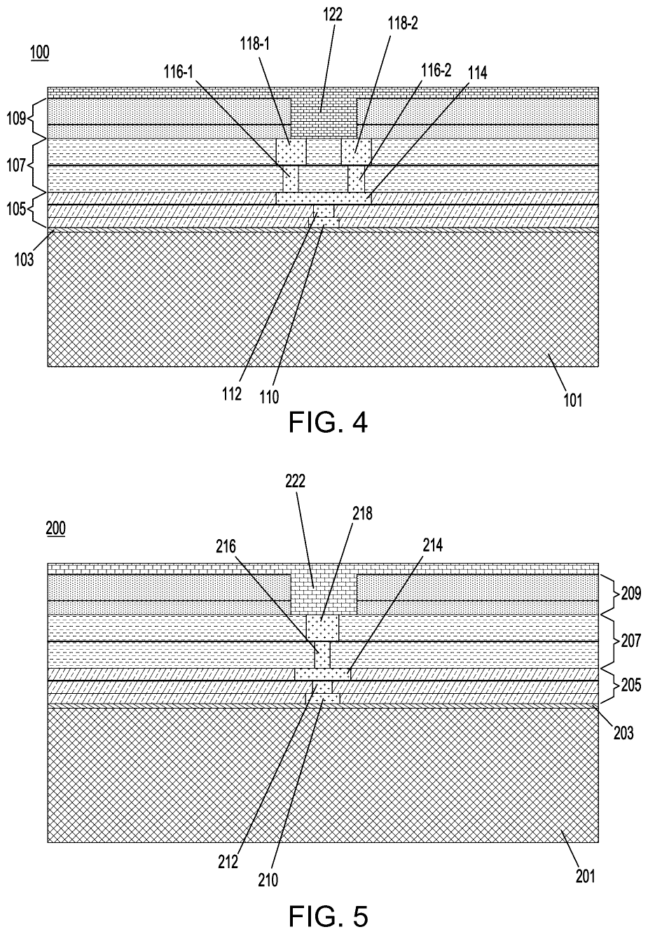

Referring to FIGS. 4 and 5, following etching of the exposed portions of the third dielectric layer stacks 109/209, the photoresists are removed and a first dielectric layer 122 and a second dielectric layer 222 are deposited on the resulting structures. According to illustrative embodiments, the material of the first and second dielectric layers 122 and 222 includes, but is not necessarily limited to, one or more of SiO₂, Si₃N₄ (silicon nitride), SiON (silicon oxynitride), and/or high-K dielectrics such as, but not necessarily limited to, HfO₂ (hafnium oxide), ZrO₂ (zirconium dioxide), and/or Ta₂O₅ (tantalum pentoxide). In the case of, for example, dynamic random-access memory (DRAM) and ferroelectric capacitor applications, complex oxides such as, for example, barium strontium titanate (BST) and/or lead zirconate titanate (PZT) can be used as the first dielectric layer 122 and a second dielectric layer 222. The choice of dielectric material depends on the specific application requirements, including the desired capacitance density, leakage characteristics, thermal stability, etc.

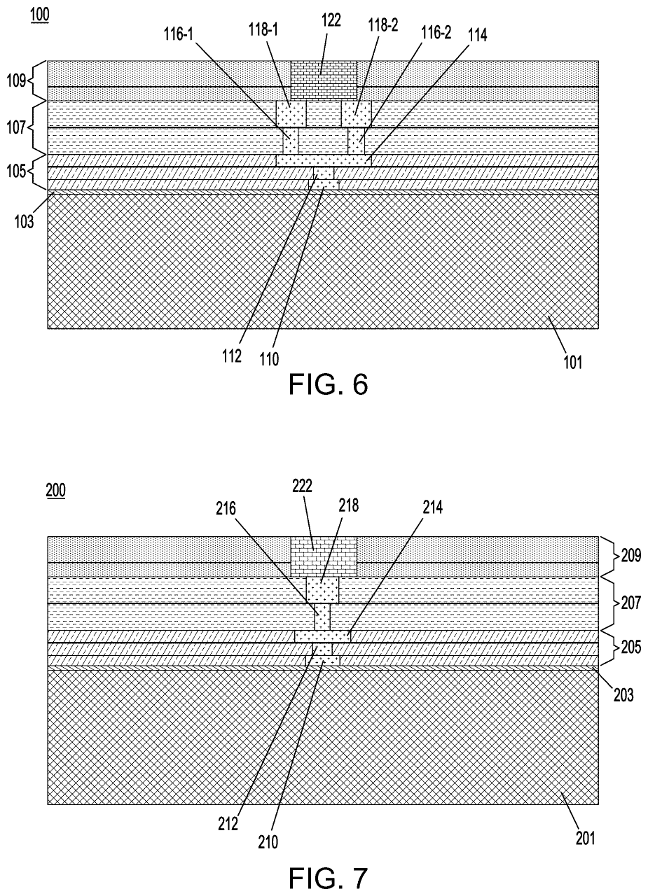

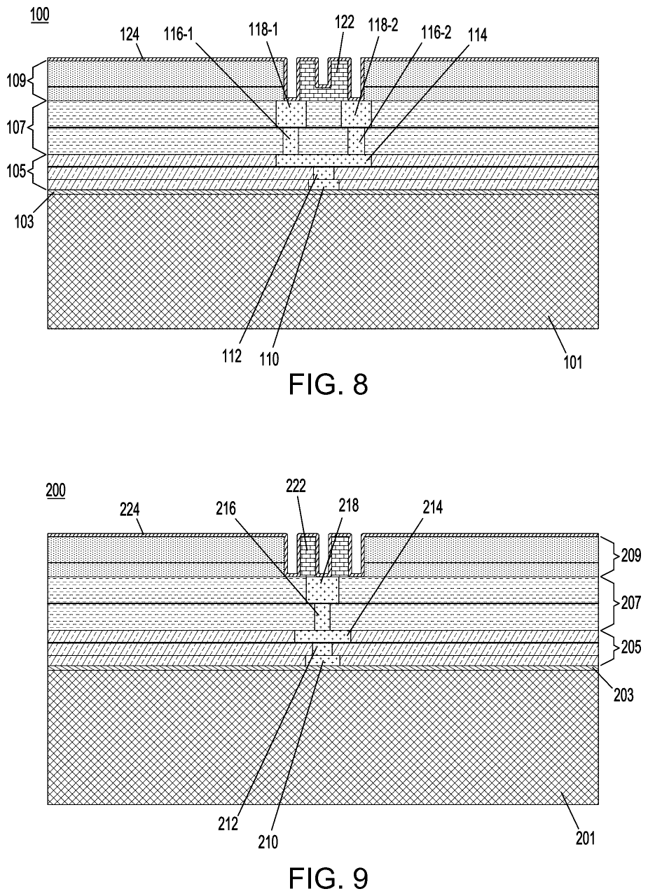

Referring to FIGS. 6 and 7, following the deposition of the first dielectric layer 122 and second dielectric layer 222, the first dielectric layer 122 and second dielectric layer 222 are planarized using, for example, a CMP process to remove portions of the first dielectric layer 122 and second dielectric layer 222 from the top surfaces of the third dielectric layer stacks 109/209. Then, referring to FIGS. 8 and 9, additional photoresists (not shown) are formed on the third dielectric layer stacks 109/209, the first dielectric layer 122 and the second dielectric layer 222 with openings exposing portions of the first dielectric layer 122 and the second dielectric layer 222. The exposed portions of the first dielectric layer 122 and the second dielectric layer 222 are etched using, for example, an RIE process, to result in the patterned first dielectric layer 122 and patterned second dielectric layer 222 shown in FIGS. 8 and 9.

A first seed/liner layer 124 is deposited on the remaining portions of the third dielectric layer stack 109, first dielectric layer 122 and the exposed portions of the two third level contacts 118-1 and 118-2 of the first semiconductor structure 100. Similarly, a second seed/liner layer 224 is deposited on the third dielectric layer stack 209, the second dielectric layer 222 and the exposed portions of the additional third level contact 218 of the second semiconductor structure 200. According to illustrative embodiments, the first and second seed/liner layers 124 and 224 each include, for example, Ti/TiW, Ti/TIN, Ta/TaN, TaN/Co, CuMn, Cu and other copper alloys.

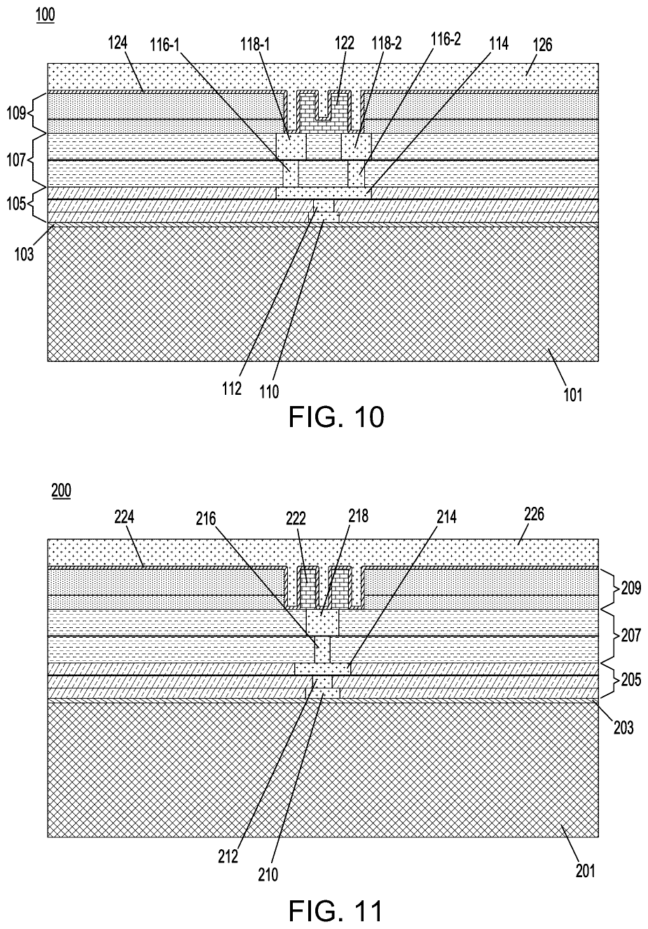

Referring to FIGS. 10 and 11, following deposition of the first and second seed/liner layers 124 and 224, a first metal fill layer 126 is formed on the first seed/liner layer 124 and a second metal fill layer 226 is formed on the second seed/liner layer 224. As can be seen in FIGS. 10 and 11, the first and second metal fill layers 126 and 226 fill-in the remaining portions of the openings in the first and second dielectric layers 122 and 222. In illustrative embodiments, the metal fill layers are formed in a plating process or other deposition process noted herein above for metal deposition, and include, for example, Cu, W, Al, Co, Ru, etc.

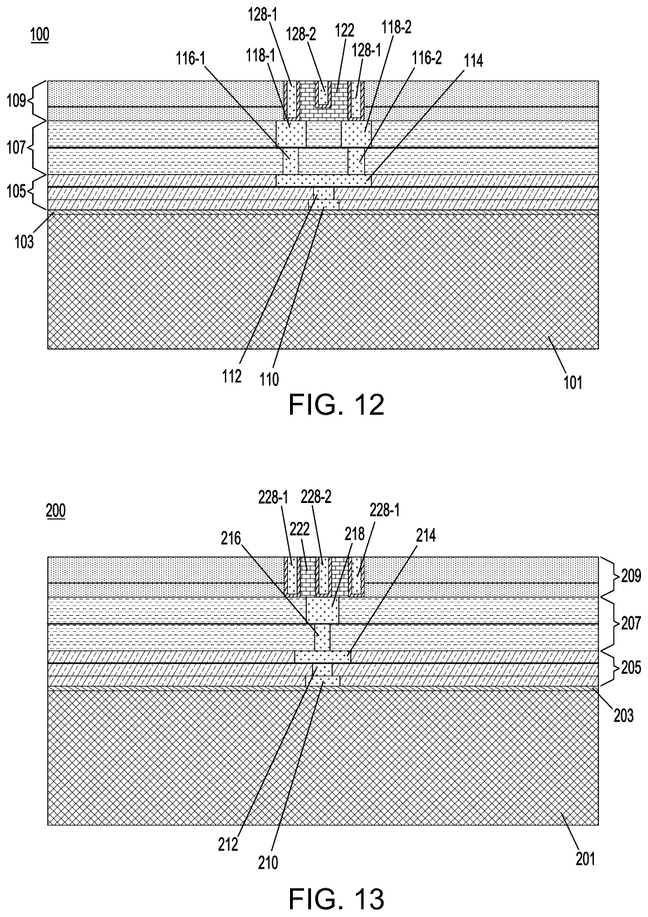

Referring to FIGS. 12 and 13, using, for example, CMP, the first and second metal fill layers 126 and 226, and the first and second seed/liner layers 124 and 224 are planarized from top surfaces first and second dielectric layers 122 and 222, and from top surfaces of the third dielectric layer stacks 109/209 of the first and second semiconductor structures 100 and 200. As can be seen in FIG. 12, and referring back to FIGS. 1A and 1B and the corresponding discussion, the first part of the capacitor structure including the first outer conductive plate portion 128-1, the first dielectric layer 122 and the first inner conductive plate portion 128-2 is formed in the first semiconductor structure 100. Similarly, as can be seen in FIG. 13, and referring back to FIGS. 1A and 1B and the corresponding discussion, the second part of the capacitor structure including the second outer conductive plate portion 228-1, the second dielectric layer 222 and the second inner conductive plate portion 228-2 is formed in the second semiconductor structure 200. The second outer conductive plate portion 228-1, the second dielectric layer 222 and the second inner conductive plate portion 228-2 are configured to be aligned with the first outer conductive plate portion 128-1, first dielectric layer 122 and first inner conductive plate portion 128-2 when hybrid bonding is performed.

Referring to FIG. 12, the first outer conductive plate portion 128-1 is connected (e.g., physically and electrically connected) to the two third level contacts 118-1 and 118-2 of the third metallization level M3, which, in turn, are connected (e.g., physically and electrically connected) to the second level contact 114 of the second metallization level M2 through the respective second vias 116-1 and 116-2. The second level contact 114 is connected (e.g., physically and electrically connected) to the first level contact 110 of the first metallization level M1 through first via 112. The first level contact 110 is at least electrically connected and can be physically connected to a first voltage source. The first inner conductive plate portion 128-2 is isolated (e.g., physically and electrically isolated) from contacts and voltage sources of the first semiconductor structure 100. With some intervening layers omitted, FIGS. 1A and 1B illustrate the first outer conductive plate portion 128-1 connected to the second level contact 114 through one or more of the second vias 116.

Referring to FIG. 13, the second inner conductive plate portion 228-2 is connected (e.g., physically and electrically connected) to the additional third level contact 218 of the other third metallization level M3′, which, in turn, is connected (e.g., physically and electrically connected) to the additional second level contact 214 of the other second metallization level M2′ through the additional second via 216. The additional second level contact 214 is connected (e.g., physically and electrically connected) to the additional first level contact 210 of the other first metallization level M1′ through the additional first via 212. The additional first level contact 210 is at least electrically connected to and can be physically connected to a second voltage source. The second outer conductive plate portion 228-1 is isolated (e.g., physically and electrically isolated) from contacts and voltage sources of the second semiconductor structure 200. With some intervening layers omitted, FIGS. 1A and 1B illustrate the second inner conductive plate portion 228-2 connected to the additional second level contact 214 through the additional second via 216.

In illustrative embodiments, the first outer conductive plate portion 128-1 and the first inner conductive plate portion 128-2 are recessed within the first dielectric layer 122 to allow for expansion of the first outer conductive plate portion 128-1 and the first inner conductive plate portion 128-2 during annealing to form the hybrid bonds. Similarly, the second outer conductive plate portion 228-1 and the second inner conductive plate portion 228-2 are recessed within the second dielectric layer 222 to allow for expansion of the second outer conductive plate portion 228-1 and the second inner conductive plate portion 228-2 during annealing to form the hybrid bonds. In a non-limiting illustrative embodiment, the amount of recessing may be in the range of about 3 nm to about 5 nm.

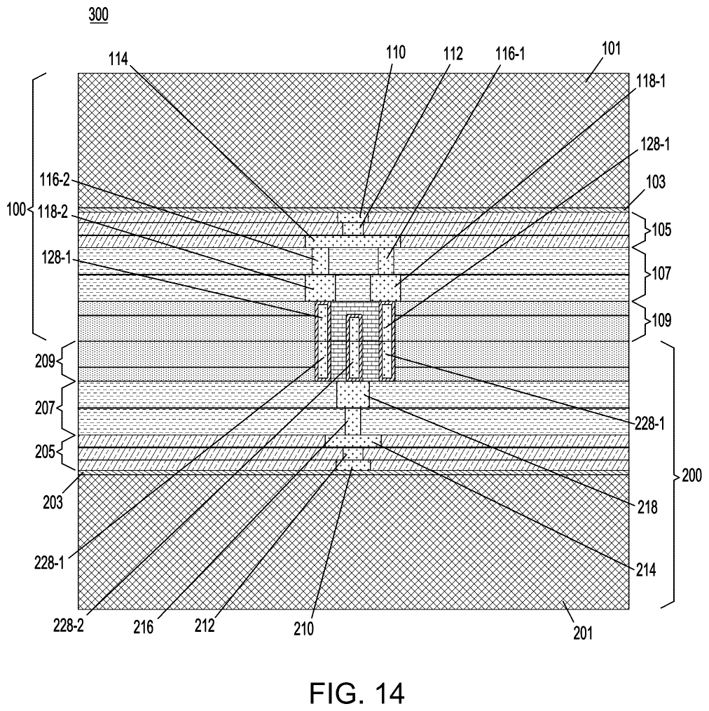

Referring to FIG. 14, in a semiconductor device 300, the first semiconductor structure 100 is flipped (e.g., rotated 180 degrees) onto the second semiconductor structure 200 so that the first semiconductor structure 100 faces the second semiconductor structure 200. As used herein, the terms “face,” “faces” or “facing” refer to the result of rotating one of two structures 180 degrees so that top surfaces of the structures can be positioned opposite and aligned with each other.

In flipping the first semiconductor structure 100 onto the second semiconductor structure 200, the first outer conductive plate portion 128-1, first dielectric layer 122 and first inner conductive plate portion 128-2 of the first semiconductor structure 100 are respectively aligned with the second outer conductive plate portion 228-1, the second dielectric layer 222 and the second inner conductive plate portion 228-2 of the second semiconductor structure 200.

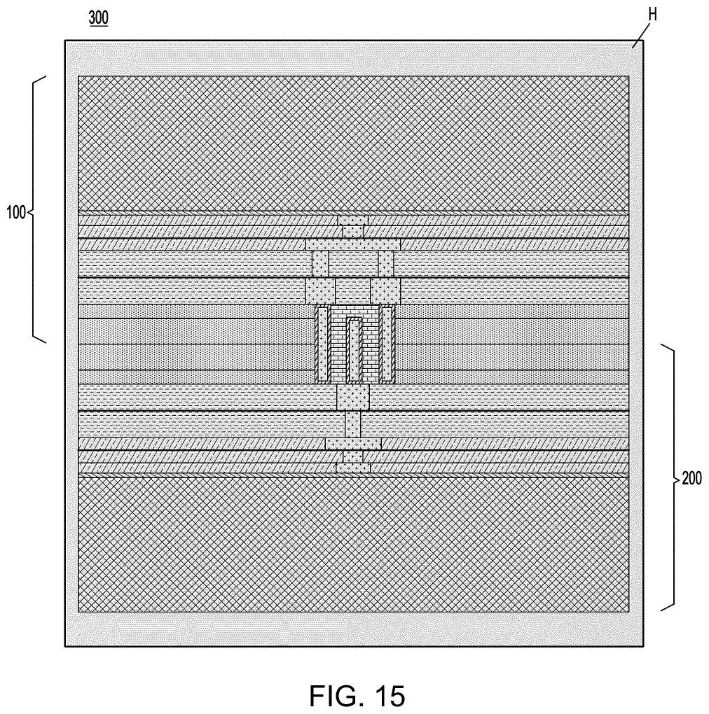

Referring to FIG. 15, a heat treatment process H is performed on the semiconductor device 300 to anneal the metal material of the first outer conductive plate portion 128-1, first inner conductive plate portion 128-2, second outer conductive plate portion 228-1 and the second inner conductive plate portion 228-2. The conditions of the heat treatment process include, for example, heat treating at about 200° C. to about 400° C. for about 1 hour to 3 hours. In an illustrative embodiment, the heat treatment is performed at 300° C. to about 400° C. for about 1 hour to about 2 hours.

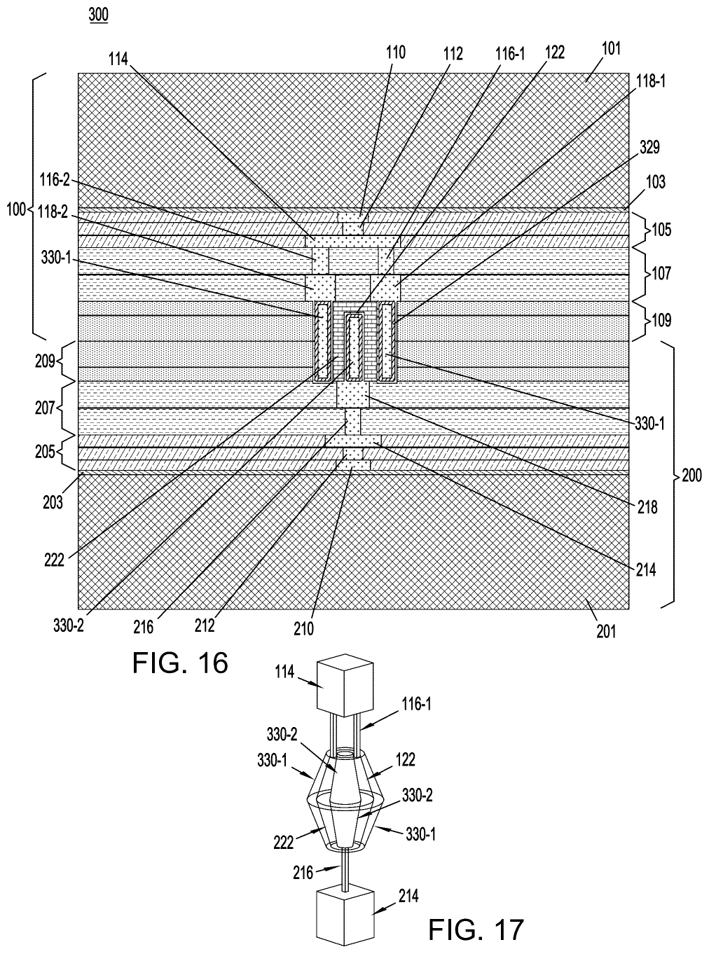

The heat treatment completes the hybrid bonding process. Referring to FIGS. 16 and 17, as a result of the annealing, the opposing first and second outer conductive plate portions 128-1 and 228-1 are formed (e.g., integrated) into an outer conductive plate 330-1 and the opposing first and second inner conductive plate portions 128-2 and 228-2 are formed (e.g., integrated) into an inner conductive plate 330-2. The outer and inner conductive plates 330-1 and 330-2 span (e.g., bridge) across an interface between the first and second semiconductor structures 100 and 200. The outer and inner conductive plates 330-1 and 330-2 are lined with a heat-treated seed/liner layer 329.

The integrated capacitor structure comprising the outer and inner conductive plates 330-1 and 330-2 and an integrated dielectric layer comprising the first and second dielectric layers 122 and 222 is disposed in the first and second semiconductor structures 100 and 200 and at an interface portion between the first and second semiconductor structures 100 and 200. Referring to FIG. 17, in an illustrative embodiment, the outer and inner conductive plates 330-1 and 330-2 and the integrated dielectric layer have a circular shape, where the outer conductive plate 330-1 (also referred to herein as a “first conductive plate”) is formed around (e.g., surrounds) the integrated dielectric layer comprising the first and second dielectric layers 122 and 222. The outer conductive plate 330-1 and the integrated dielectric layer are formed around (e.g., surround) the inner conductive plate 330-2 (also referred to herein as a “second conductive plate”). The outer conductive plate 330-1, the integrated dielectric layer, and the inner conductive plate 330-2 are concentric. The inner conductive plate 330-2 is inlayed within the integrated dielectric layer and within the first conductive plate 330-1, and the integrated dielectric layer is inlayed within the outer conductive plate 330-1. As can be understood, in illustrative embodiments, the outer conductive plate 330-1 has a hollow central portion in which the integrated dielectric layer is formed, and in which the inner conductive plate 330-2 is formed. As an alternative to being circular, the outer and inner conductive plates 330-1 and 330-2 and the integrated dielectric layer can have an oval shape.

The outer conductive plate 330-1 is connected (e.g., physically and electrically connected) to the two third level contacts 118-1 and 118-2 of the third metallization level M3, which, in turn, are connected (e.g., physically and electrically connected) to the second level contact 114 of the second metallization level M2 through the respective second vias 116-1 and 116-2. The second level contact 114 is connected (e.g., physically and electrically connected) to the first level contact 110 of the first metallization level M1 through first via 112. The first level contact 110 is at least electrically connected to and can be physically connected to a first voltage source. The inner conductive plate 330-2 is isolated (e.g., physically and electrically isolated) from contacts and voltage sources of the first semiconductor structure 100. The inner conductive plate 330-2 is connected (e.g., physically and electrically connected) to the additional third level contact 218 of the other third metallization level M3′, which, in turn, is connected (e.g., physically and electrically connected) to the additional second level contact 214 of the other second metallization level M2′ through the additional second via 216. The additional second level contact 214 is connected (e.g., physically and electrically connected) to the additional first level contact 210 of the other first metallization level M1′ through the additional first via 212. The additional first level contact 210 is at least electrically connected to and can be physically connected to a second voltage source. The outer conductive plate 330-1 is isolated (e.g., physically and electrically isolated) from contacts and voltage sources of the second semiconductor structure 200.

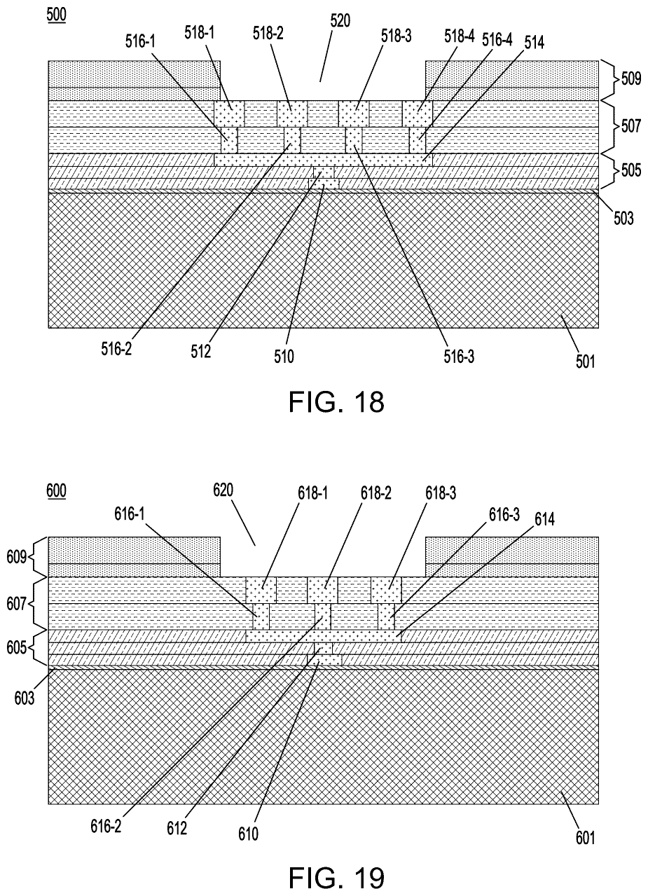

Referring to FIGS. 18 and 19, in an alternative embodiment, third and fourth semiconductor structures 500 and 600 include another first semiconductor substrate 501 and another second semiconductor substrate 601, respectively. The other first and second semiconductor substrates 501 and 601 are the same as or similar to the first and second semiconductor substrates 101 and 201, including the same or similar semiconductor materials. Respective other first and second base dielectric hermetic layers 503 and 603, which the same as or similar to the first and second base dielectric hermetic layers 103 and 203, are formed on the other first and second semiconductor substrates 501 and 601.

Like the first and second semiconductor structures 100 and 200, the third and fourth semiconductor structures 500 and 600 each include another first dielectric layer stack 505/605, another second dielectric layer stack 507/607 on the other first dielectric layer stack 505/605 and another third dielectric layer stack 509/609 on the other second dielectric layer stack 507/607. In illustrative embodiments, the other first, second and third dielectric layer stacks 505/605, 507/607 and 509/609 include, but are not necessarily limited to, the same materials and configuration as or similar configuration and materials to the first, second and third dielectric layer stacks 105/205, 107/207 and 109/209.

Similar to the first semiconductor structure 100, the third semiconductor structure 500 includes a first metallization level M1, a second metallization level M2 and a third metallization level M3. In the third semiconductor structure 500, the first metallization level M1 includes a first level contact 510, the second metallization level M2 includes a second level contact 514, and the third metallization level M3 includes four third level contacts 518-1, 518-2, 518-3 and 518-4. A first via 512 connects the first level contact 510 and the second level contact 514. Respective second vias 516-1, 516-2, 516-3 and 516-4 connect the four third level contacts 518-1, 518-2, 518-3 and 518-4 to the second level contact 514. The first level contact 510, first via 512 and second level contact 514 are formed in the first dielectric layer stack 505 of the third semiconductor structure 500. The four third level contacts 518-1, 518-2, 518-3 and 518-4 and second vias 516-1, 516-2, 516-3 and 516-4 are formed in the second dielectric layer stack 507 of the third semiconductor structure 500.

Similar to the second semiconductor structure 200, the fourth semiconductor structure 600 includes another first metallization level M1′, another second metallization level M2′ and another third metallization level M3′. The other first metallization level M1′ includes an additional first level contact 610, the other second metallization level M2′ includes an additional second level contact 614, and the other third metallization level M3′ includes three additional third level contacts 618-1, 618-2 and 618-3. An additional first via 612 connects the additional first level contact 610 and the additional second level contact 614. Three additional second vias 616-1, 616-2 and 616-3 respectively connect the three additional third level contacts 618-1, 618-2 and 618-3 to the additional second level contact 614. The additional first level contact 610, additional first via 612 and additional second level contact 614 are formed in the first dielectric layer stack 605 of the fourth semiconductor structure 600. The three additional third level contacts 618-1, 618-2 and 618-3 and the three additional second vias 616-1, 616-2 and 616-3 are formed in the second dielectric layer stack 607 of the fourth semiconductor structure 600.

The metallization levels M1, M1′, M2, M2′, M3 and M3′ of the third and fourth semiconductor structures 500 and 600 can include, for example, wiring that is present on a chip, including, for example, multiple metal levels corresponding to circuit wiring, bussing, power distribution, input-output (I/O), backside power rails or other voltage or signal sources, etc.

In illustrative embodiments, the contacts 510, 514, 518-1, 518-2, 518-3, 518-4, 610, 614, 618-1, 618-2 and 618-3, and the vias 512, 516-1, 516-2, 516-3, 516-4, 612, 616-1, 616-2 and 616-3 of the third and fourth semiconductor structures 500 and 600 include, for example, the same or similar materials as the contacts 110, 114, 118-1, 118-2, 210, 214 and 218, and the vias 112, 116-1, 116-2, 212 and 216 of the first and second semiconductor structures 100 and 200. The contacts 510, 514, 518-1, 518-2, 518-3, 518-4, 610, 614, 618-1, 618-2 and 618-3, and the vias 512, 516-1, 516-2, 516-3, 516-4, 612, 616-1, 616-2 and 616-3 of the third and fourth semiconductor structures 500 and 600 can be formed using the same or similar techniques as those used for the contacts 110, 114, 118-1, 118-2, 210, 214 and 218, and the vias 112, 116-1, 116-2, 212 and 216 of the first and second semiconductor structures 100 and 200.

Photoresists (not shown) are patterned to create openings corresponding to where parts of capacitor structures are to be formed. The openings in the photoresists expose portions of the third dielectric layer stacks 509/609 of the third and fourth semiconductor structures 500 and 600 that are etched to create other first and second openings 520 and 620 respectively exposing portions of the four third level contacts 518-1, 518-2, 518-3 and 518-4 of the third semiconductor structure 500 and the three additional third level contacts 618-1, 618-2 and 618-3 of the fourth semiconductor structure 600. The etch can be performed using a RIE process.

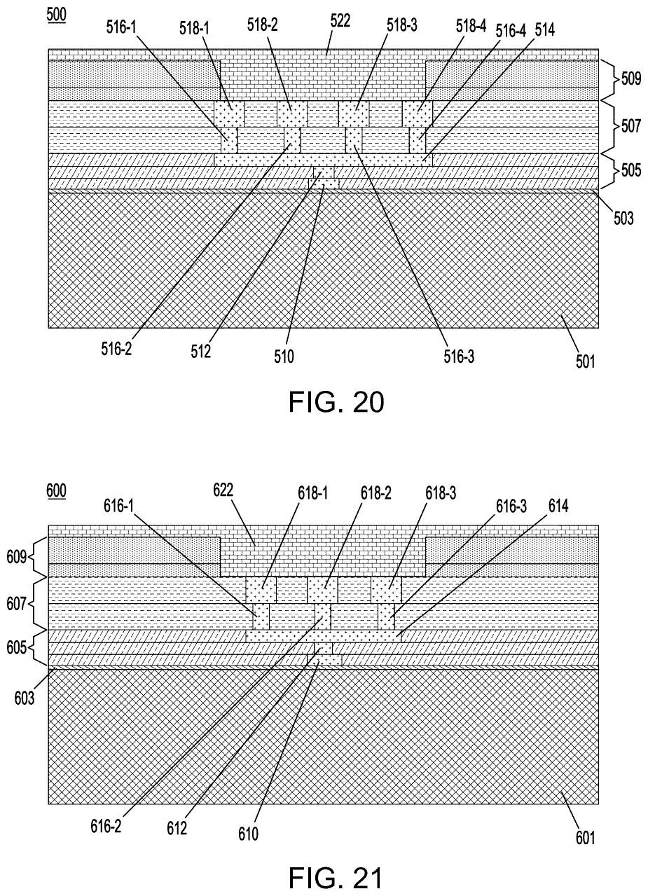

Referring to FIGS. 20 and 21, following etching of the exposed portions of the third dielectric layer stacks 509/609 of the third and fourth semiconductor structures 500 and 600, the photoresists are removed and another first dielectric layer 522 and another second dielectric layer 622 are deposited on the resulting structures. According to illustrative embodiments, the material of the other first and second dielectric layers 522 and 622 of the third and fourth semiconductor structures 500 and 600 is the same as that of the first and second dielectric layers 122 and 222 of the first and second semiconductor structures 100 and 200 and includes, but is not necessarily limited to, one or more of SiO₂, Si₃N₄, SiON, and/or high-K dielectrics such as, but not necessarily limited to, HfO₂, ZrO₂, and/or Ta₂O₅. In the case of, for example, DRAM and ferroelectric capacitor applications, complex oxides such as, for example, BST and/or PZT can be used as the other first dielectric layer 522 and the other second dielectric layer 622. The choice of dielectric material depends on the specific application requirements, including the desired capacitance density, leakage characteristics, thermal stability, etc.

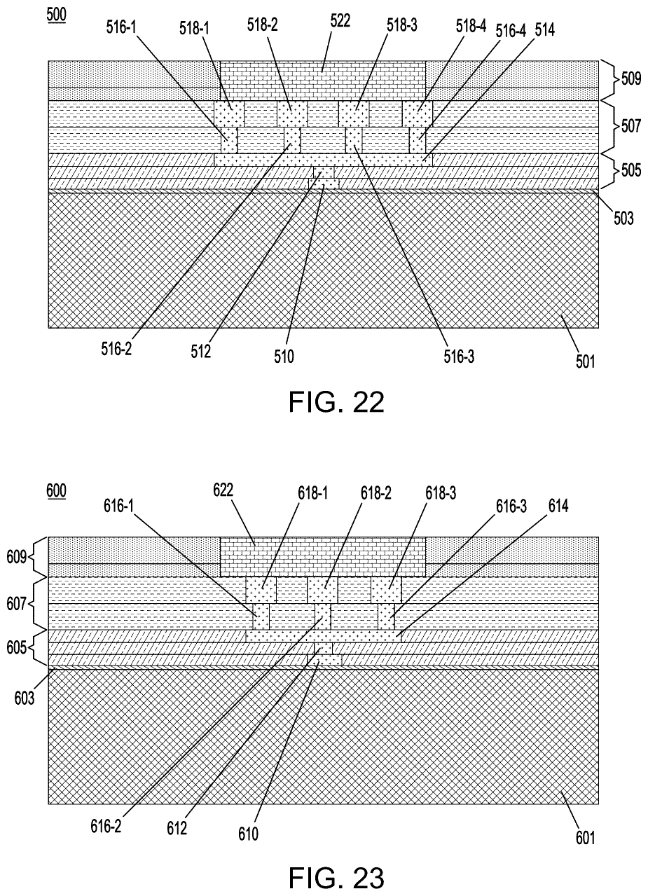

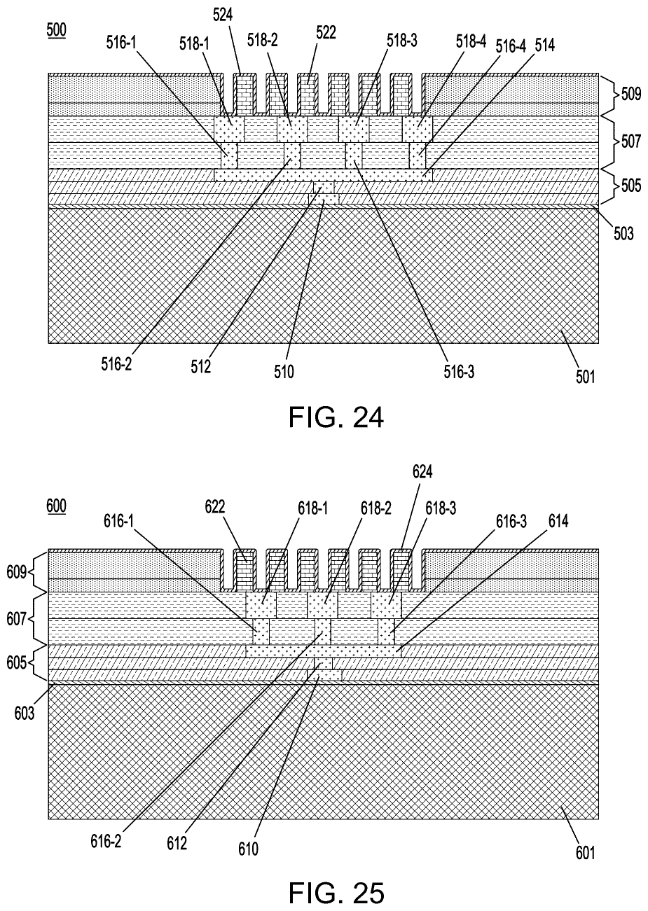

Referring to FIGS. 22 and 23, following the deposition of the other first dielectric layer 522 and other second dielectric layer 622, the other first dielectric layer 522 and other second dielectric layer 622 are planarized using, for example, a CMP process to remove portions of the other first dielectric layer 522 and other second dielectric layer 622 from the top surfaces of the third dielectric layer stacks 509/609 of the third and fourth semiconductor structures 500 and 600. Then, referring to FIGS. 24 and 25, additional photoresists (not shown) are formed on the third dielectric layer stacks 109/209, the other first dielectric layer 522 and the other second dielectric layer 622 of the third and fourth semiconductor structures 500 and 600 with openings exposing portions of the other first dielectric layer 522 and the other second dielectric layer 622. The exposed portions of the other first dielectric layer 522 and the other second dielectric layer 622 are etched using, for example, a RIE process, to result in the patterned other first dielectric layer 522 and patterned other second dielectric layer 622 shown in FIGS. 24 and 25.

Another first seed/liner layer 524 is deposited on the remaining portions of the third dielectric layer stack 509, other first dielectric layer 522 and the exposed portions of the four third level contacts 518-1, 518-2, 518-3 and 518-4 of the third semiconductor structure 500. Similarly, another second seed/liner layer 624 is deposited on the third dielectric layer stack 609, the other second dielectric layer 622 and the exposed portions of the three additional third level contact 618-1, 618-2 and 618-3 of the fourth semiconductor structure 600. According to illustrative embodiments, the other first and second seed/liner layers 524 and 624 each include, for example, Ti/TiW, Ti/TiN, Ta/TaN, TaN/Co, CuMn, Cu and other copper alloys.

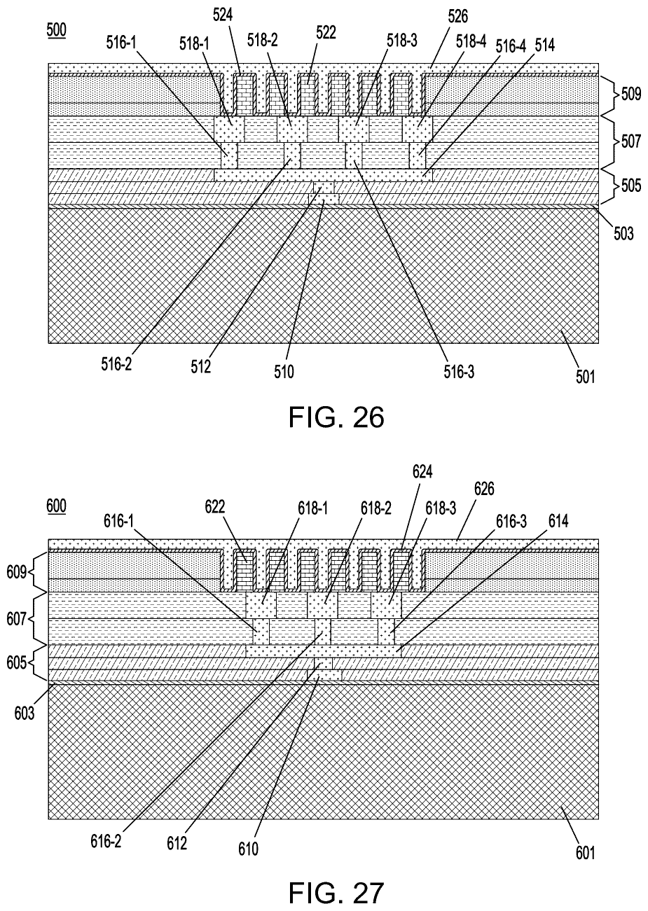

Referring to FIGS. 26 and 27, following deposition of the other first and second seed/liner layers 524 and 624, another first metal fill layer 526 is formed on the other first seed/liner layer 524 and another second metal fill layer 626 is formed on the other second seed/liner layer 624. As can be seen in FIGS. 26 and 27, the other first and second metal fill layers 526 and 626 fill-in the remaining portions of the openings in the other first and second dielectric layers 522 and 622. In illustrative embodiments, the metal fill layers are formed in a plating process or other deposition process noted herein above for metal deposition, and include, for example, Cu, W, Al, Co, Ru, etc.

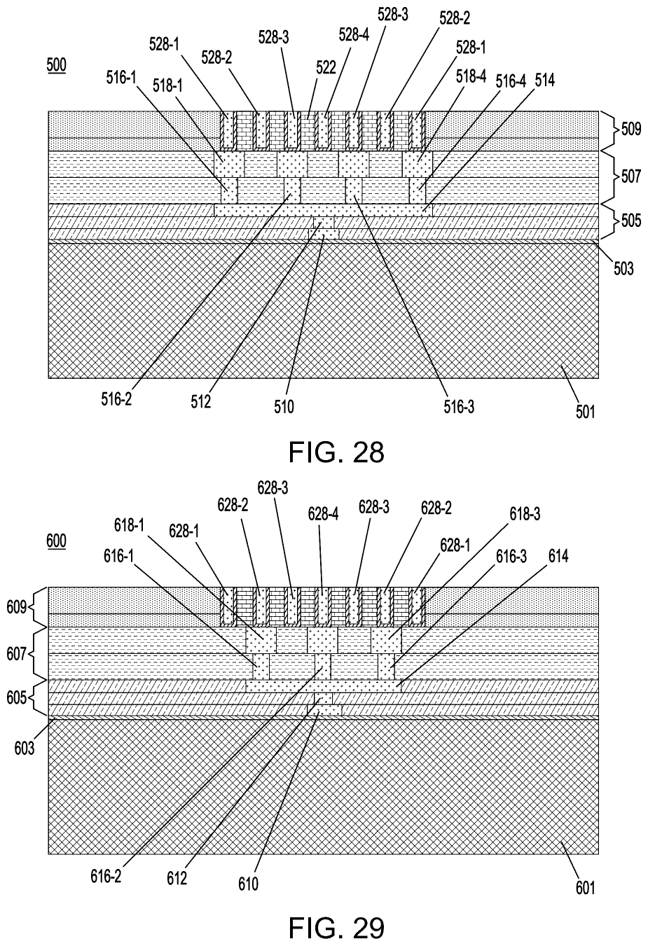

Referring to FIGS. 28 and 29, using, for example, CMP, the other first and second metal fill layers 526 and 626, and the other first and second seed/liner layers 524 and 624 are planarized from top surfaces of the other first and second dielectric layers 522 and 622, and from top surfaces of the third dielectric layer stacks 509/609 of the third and fourth semiconductor structures 500 and 600. As can be seen in FIG. 28, a first part of a capacitor structure formed in the third semiconductor structure 500 includes a first outermost conductive plate portion 528-1, a first portion of the other first dielectric layer 522, a first outermost adjacent conductive plate portion 528-2, a second portion of the other first dielectric layer 522, a first innermost adjacent conductive plate portion 528-3, a third portion of the other first dielectric layer 522 and a first innermost conductive plate portion 528-4. Similarly, as can be seen in FIG. 29, a second part of a capacitor structure formed in the fourth semiconductor structure 600 includes a second outermost conductive plate portion 628-1, a first portion of the other second dielectric layer 622, a second outermost adjacent conductive plate portion 628-2, a second portion of the other second dielectric layer 622, a second innermost adjacent conductive plate portion 628-3, a third portion of the other second dielectric layer 622 and a second innermost conductive plate portion 628-4. The second outermost conductive plate portion 628-1, first portion of the other second dielectric layer 622, second outermost adjacent conductive plate portion 628-2, second portion of the other second dielectric layer 622, second innermost adjacent conductive plate portion 628-3, third portion of the other second dielectric layer 622 and second innermost conductive plate portion 628-4 are configured to be aligned with the first outermost conductive plate portion 528-1, first portion of the other first dielectric layer 522, first outermost adjacent conductive plate portion 528-2, second portion of the other first dielectric layer 522, first innermost adjacent conductive plate portion 528-3, third portion of the other first dielectric layer 522 and first innermost conductive plate portion 528-4 when hybrid bonding is performed.

Referring to FIG. 28, the first outermost conductive plate portion 528-1 is connected (e.g., physically and electrically connected) to two third level contacts 518-1 and 518-4 of the third metallization level M3 of the third semiconductor structure 500 and the first innermost adjacent conductive plate portion 528-3 is connected (e.g., physically and electrically connected) to the remaining two third level contacts 518-2 and 518-3 of the third metallization level M3 of the third semiconductor structure 500. The third level contacts 518-1 to 518-4 are, in turn, connected (e.g., physically and electrically connected) to the second level contact 514 of the second metallization level M2 of the third semiconductor structure 500 through respective second vias 516-1, 516-2, 516-3 and 516-4. The second level contact 514 is connected (e.g., physically and electrically connected) to the first level contact 510 of the first metallization level M1 of the third semiconductor structure 500 through first via 512. The first level contact 510 is at least electrically connected and can be physically connected to a first voltage source. The first outermost adjacent conductive plate portion 528-2 and the first innermost conductive plate portion 528-4 are isolated (e.g., physically and electrically isolated) from contacts and voltage sources of the third semiconductor structure 500.

Referring to FIG. 29, the second outermost adjacent conductive plate portion 628-2 is connected (e.g., physically and electrically connected) to two additional third level contacts 618-1 and 618-3 of the other third metallization level M3′ of the fourth semiconductor structure 600 and the second innermost conductive plate portion 628-4 is connected (e.g., physically and electrically connected) to the remaining additional third level contact 618-2 of the other third metallization level M3′ of the fourth semiconductor structure 600. The three additional third level contacts 618-1, 618-2 and 618-3 are, in turn, connected (e.g., physically and electrically connected) to the additional second level contact 614 of the other second metallization level M2′ of the fourth semiconductor structure 600 through the three additional second vias 616-1, 616-2 and 616-3. The additional second level contact 614 is connected (e.g., physically and electrically connected) to the additional first level contact 610 of the other first metallization level M1′ of the fourth semiconductor structure 600 through the additional first via 612. The additional first level contact 610 is at least electrically connected and can be physically connected to a second voltage source. The second outermost conductive plate portion 628-1 and the second innermost adjacent conductive plate portion 628-3 are isolated (e.g., physically and electrically isolated) from contacts and voltage sources of the fourth semiconductor structure 600.

In illustrative embodiments, the first outermost conductive plate portion 528-1, the first outermost adjacent conductive plate portion 528-2, the first innermost adjacent conductive plate portion 528-3 and the first innermost conductive plate portion 528-4 are recessed within the other first dielectric layer 522 to allow for expansion of the first outermost conductive plate portion 528-1, the first outermost adjacent conductive plate portion 528-2, the first innermost adjacent conductive plate portion 528-3 and the first innermost conductive plate portion 528-4 during annealing to form the hybrid bonds. Similarly, the second outermost conductive plate portion 628-1, the second outermost adjacent conductive plate portion 628-2, the second innermost adjacent conductive plate portion 628-3 and the second innermost conductive plate portion 628-4 are recessed within the other second dielectric layer 622 to allow for expansion of the second outermost conductive plate portion 628-1, the second outermost adjacent conductive plate portion 628-2, the second innermost adjacent conductive plate portion 628-3 and the second innermost conductive plate portion 628-4 during annealing to form the hybrid bonds. In a non-limiting illustrative embodiment, the amount of recessing may be in the range of about 3 nm to about 5 nm.

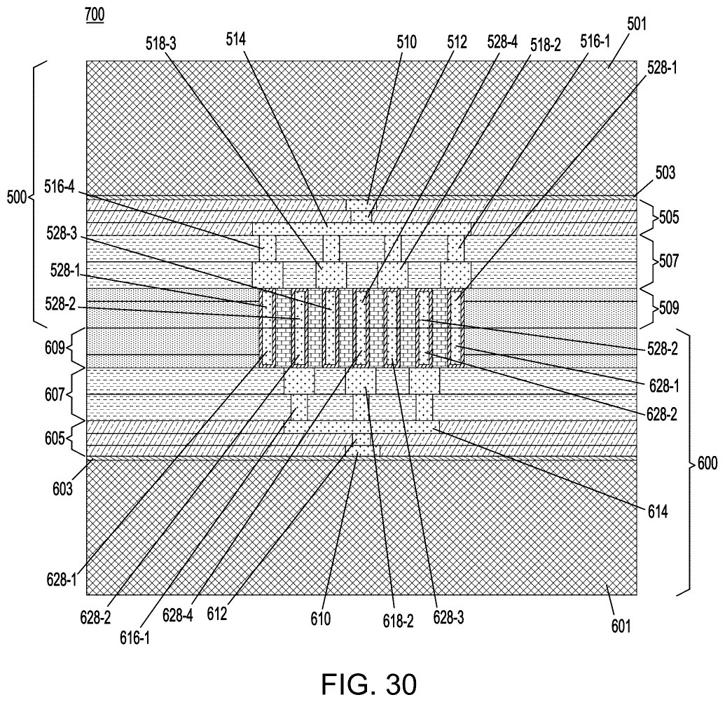

Referring to FIG. 30, in a semiconductor device 700, the third semiconductor structure 500 is flipped (e.g., rotated 180 degrees) onto the fourth semiconductor structure 600 so that the third semiconductor structure 500 faces the fourth semiconductor structure 600. As used herein, the terms “face,” “faces” or “facing” refer to the result of rotating one of two structures 180 degrees so that top surfaces of the structures can be positioned opposite and aligned with each other.

In flipping the third semiconductor structure 500 onto fourth semiconductor structure 600, the first outermost conductive plate portion 528-1, first portion of the other first dielectric layer 522, first outermost adjacent conductive plate portion 528-2, second portion of the other first dielectric layer 522, first innermost adjacent conductive plate portion 528-3, third portion of the other first dielectric layer 522 and first innermost conductive plate portion 528-4 of the third semiconductor structure 500 are respectively aligned with the second outermost conductive plate portion 628-1, first portion of the other second dielectric layer 622, second outermost adjacent conductive plate portion 628-2, second portion of the other second dielectric layer 622, second innermost adjacent conductive plate portion 628-3, third portion of the other second dielectric layer 622 and second innermost conductive plate portion 628-4 of the fourth semiconductor structure 600.

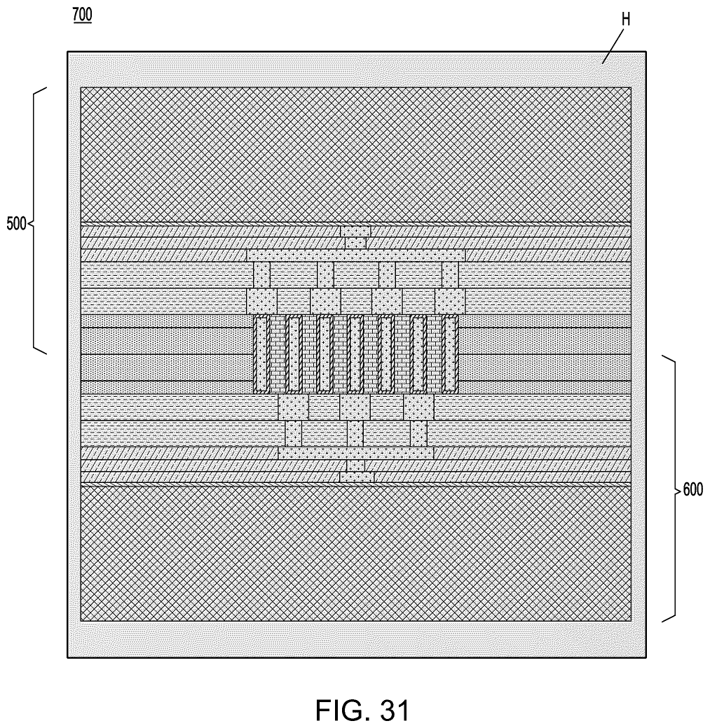

Referring to FIG. 31, a heat treatment process H is performed on the semiconductor device 700 to anneal the metal material of the first outermost conductive plate portion 528-1, first outermost adjacent conductive plate portion 528-2, first innermost adjacent conductive plate portion 528-3, first innermost conductive plate portion 528-4, second outermost conductive plate portion 628-1, second outermost adjacent conductive plate portion 628-2, second innermost adjacent conductive plate portion 628-3, and second innermost conductive plate portion 628-4. The conditions of the heat treatment process include, for example, heat treating at about 200° C. to about 400° C. for about 1 hour to 3 hours. In an illustrative embodiment, the heat treatment is performed at 300° C. to about 400° C. for about 1 hour to about 2 hours.

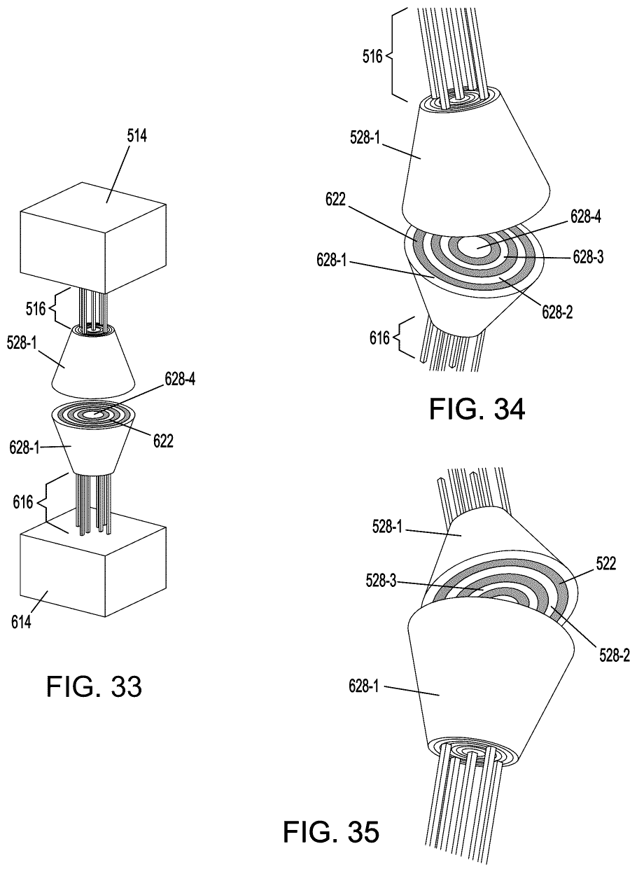

The heat treatment completes the hybrid bonding process. Referring to FIGS. 32-35, as a result of the annealing, the opposing first and second outermost conductive plate portions 528-1 and 628-1 are formed (e.g., integrated) into an outermost conductive plate 730-1, opposing first and second outermost adjacent conductive plate portions 528-2 and 628-2 are formed (e.g., integrated) into an outermost adjacent conductive plate 730-2, opposing first and second innermost adjacent conductive plate portions 528-3 and 628-3 are formed (e.g., integrated) into an innermost adjacent conductive plate 730-3, and the opposing first and second innermost conductive plate portions 528-4 and 628-4 are formed (e.g., integrated) into an innermost conductive plate 730-4. The outermost conductive plate 730-1, outermost adjacent conductive plate 730-2, innermost adjacent conductive plate 730-3 and innermost conductive plate 730-4 span (e.g., bridge) across an interface between the third and fourth semiconductor structures 500 and 600. The outermost conductive plate 730-1, outermost adjacent conductive plate 730-2, innermost adjacent conductive plate 730-3 and innermost conductive plate 730-4 are lined with a heat-treated seed/liner layer 729.

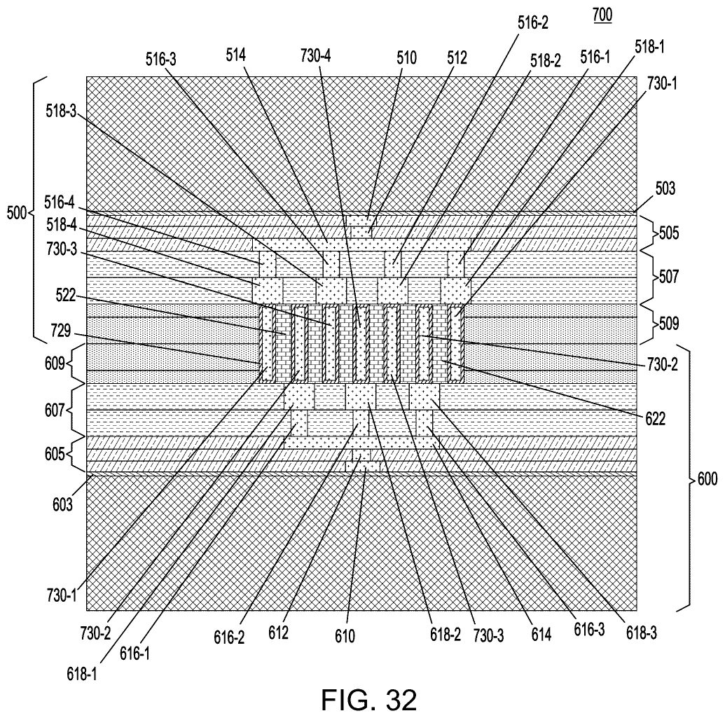

The integrated capacitor structure comprising the outermost conductive plate 730-1, outermost adjacent conductive plate 730-2, innermost adjacent conductive plate 730-3 and innermost conductive plate 730-4 and integrated dielectric layer portions comprising the other first and other second dielectric layers 522 and 622 is disposed in the third and fourth semiconductor structures 500 and 600 and at an interface portion between the third and fourth semiconductor structures 500 and 600. Referring to FIGS. 33-35, in an illustrative embodiment, the outermost conductive plate 730-1, outermost adjacent conductive plate 730-2, innermost adjacent conductive plate 730-3 and innermost conductive plate 730-4 and an integrated dielectric layer portions have a circular shape. In more detail, the outermost conductive plate 730-1 is formed around (e.g., surrounds) a first portion of the integrated dielectric layer comprising the other first and other second dielectric layers 522 and 622. The outermost conductive plate 730-1 and the first portion of the integrated dielectric layer are formed around the outermost adjacent conductive plate 730-2, which is formed around (e.g., surrounds) a second portion of the integrated dielectric layer comprising the other first and other second dielectric layers 522 and 622. The second portion of the integrated dielectric layer is formed around (e.g., surrounds) the innermost adjacent conductive plate 730-3, which is formed around (e.g., surrounds) a third portion of the integrated dielectric layer comprising the other first and other second dielectric layers 522 and 622. The third portion of the integrated dielectric layer comprising the other first and other second dielectric layers 522 and 622 is formed around (e.g., surrounds) the innermost conductive plate 730-4. The outermost conductive plate 730-1, outermost adjacent conductive plate 730-2, innermost adjacent conductive plate 730-3 and innermost conductive plate 730-4 and integrated dielectric layer portions are concentric. The innermost conductive plate 730-4 is inlayed within the layers surrounding it (e.g., within the first-third portions of the integrated dielectric layer, the outermost conductive plate 730-1, outermost adjacent conductive plate 730-2 and innermost adjacent conductive plate 730-3). The third portion of the integrated dielectric layer is inlayed within the layers surrounding it (e.g., within the first and second portions of the integrated dielectric layer, the outermost conductive plate 730-1, outermost adjacent conductive plate 730-2 and innermost adjacent conductive plate 730-3). The innermost adjacent conductive plate 730-3 is inlayed within the layers surrounding it (e.g., within the first and second portions of the integrated dielectric layer, the outermost conductive plate 730-1, and the outermost adjacent conductive plate 730-2). The second portion of the integrated dielectric layer is inlayed within the layers surrounding it (e.g., within the first portion of the integrated dielectric layer, the outermost conductive plate 730-1 and outermost adjacent conductive plate 730-2). The outermost adjacent conductive plate 730-2 is inlayed within the layers surrounding it (e.g., within the first portion of the integrated dielectric layer and the outermost conductive plate 730-1). The first portion of the integrated dielectric layer is inlayed within the outermost conductive plate 730-1. As can be understood, in illustrative embodiments, the outermost conductive plate 730-1, outermost adjacent conductive plate 730-2 and innermost adjacent conductive plate 730-3 each have hollow central portions in which the inlayed layers are formed.

The outermost conductive plate 730-1 is connected (e.g., physically and electrically connected) to two third level contacts 518-1 and 518-4 of the third metallization level M3 of the third semiconductor structure 500 and the innermost adjacent conductive plate 730-3 is connected (e.g., physically and electrically connected) to the remaining two third level contacts 518-2 and 518-3 of the third metallization level M3 of the third semiconductor structure 500. The third level contacts 518-1 to 518-4 are, in turn, connected (e.g., physically and electrically connected) to the second level contact 514 of the second metallization level M2 of the third semiconductor structure 500 through respective second vias 516-1, 516-2, 516-3 and 516-4. The second level contact 514 is connected (e.g., physically and electrically connected) to the first level contact 510 of the first metallization level M1 of the third semiconductor structure 500 through first via 512. The first level contact 510 is at least electrically connected and can be physically connected to a first voltage source. The outermost adjacent conductive plate 730-2 and the innermost conductive plate 730-4 are isolated (e.g., physically and electrically isolated) from contacts and voltage sources of the third semiconductor structure 500.

The outermost adjacent conductive plate 730-2 is connected (e.g., physically and electrically connected) to two additional third level contacts 618-1 and 618-3 of the other third metallization level M3′ of the fourth semiconductor structure 600 and the innermost conductive plate 730-4 is connected (e.g., physically and electrically connected) to the remaining additional third level contact 618-2 of the other third metallization level M3′ of the fourth semiconductor structure 600. The three additional third level contacts 618-1, 618-2 and 618-3 are, in turn, connected (e.g., physically and electrically connected) to the additional second level contact 614 of the other second metallization level M2′ of the fourth semiconductor structure 600 through the three additional second vias 616-1, 616-2 and 616-3. The additional second level contact 614 is connected (e.g., physically and electrically connected) to the additional first level contact 610 of the other first metallization level M1′ of the fourth semiconductor structure 600 through the additional first via 612. The additional first level contact 210 is at least electrically connected and may be physically connected to a second voltage source. The outermost conductive plate 730-1 and the innermost adjacent conductive plate 730-3 are isolated (e.g., physically and electrically isolated) from contacts and voltage sources of the fourth semiconductor structure 600.

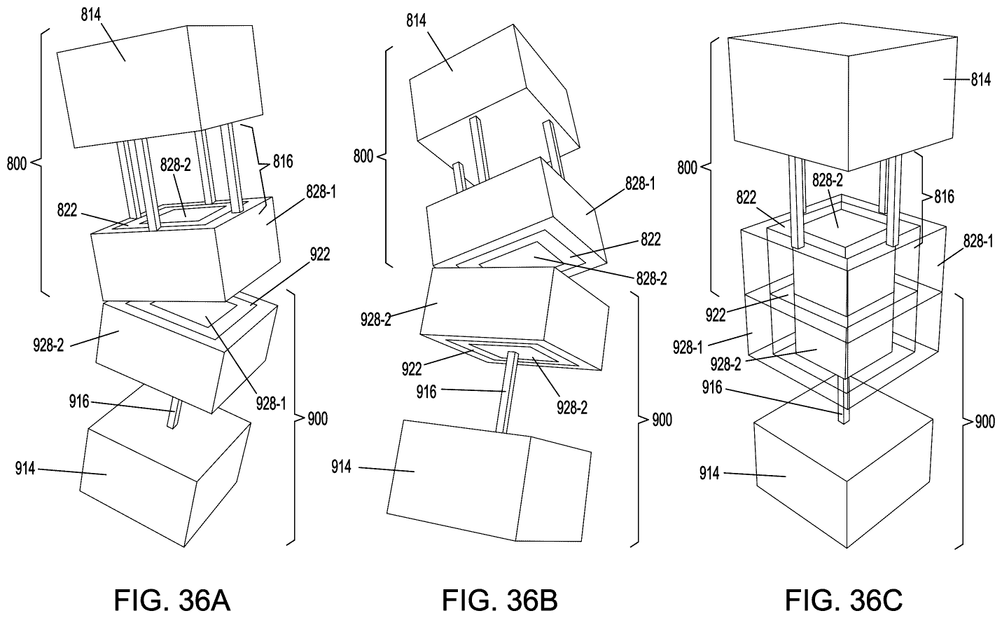

Referring to FIGS. 36A, 36B and 36C, an alternative embodiment in which capacitor element layers are square or rectangular instead of circular is shown. In more detail, a first alternative semiconductor structure 800 and a second alternative semiconductor structure 900 are each manufactured to include parts of a capacitor structure, each part comprising an outer conductive plate portion, a dielectric layer and an inner conductive plate portion. When the first alternative semiconductor structure 800 is hybrid bonded to the second alternative semiconductor structure 900, an integrated capacitor structure is formed comprising an integrated outer conductive plate, an integrated dielectric layer and an integrated inner conductive plate. The integrated capacitor structure is disposed in the first and second alternative semiconductor structures 800 and 900 and at an interface portion between the first and second alternative semiconductor structures 800 and 900.

In more detail, a first part of the capacitor structure forming part of a first alternative semiconductor structure 800 includes a first alternative outer conductive plate portion 828-1, a first alternative dielectric layer 822 and a first alternative inner conductive plate portion 828-2, each in a square or rectangular shape. Similarly, a second part of the capacitor structure forming part of the second alternative semiconductor structure 900 includes a second alternative outer conductive plate portion 928-1, a second alternative dielectric layer 922 and a second alternative inner conductive plate portion 928-2, each in a square or rectangular shape, and configured to be aligned with the first alternative outer conductive plate portion 828-1, first alternative dielectric layer 822 and first alternative inner conductive plate portion 828-2 when hybrid bonding is performed.

In FIGS. 36A-36C, the parts of the capacitor structure of the first and second alternative semiconductor structures 800 and 900 have the square or rectangular shape, where the first and second alternative outer conductive plate portions 828-1 and 928-1 are respectively formed around (e.g., surround) the first and second alternative dielectric layers 822 and 922, which are respectively formed around (e.g., surround) the first and second alternative inner conductive plate portions 828-2 and 928-2. The first alternative outer conductive plate portion 828-1, the first alternative dielectric layer 822, and the first alternative inner conductive plate portion 828-2 are concentric, and the second alternative outer conductive plate portion 928-1, the second alternative dielectric layer 922, and the second alternative inner conductive plate portion 928-2 are concentric. The first alternative inner conductive plate portion 828-2 is inlayed within the first alternative dielectric layer 822 and within the first alternative outer conductive plate portion 828-1, and the first alternative dielectric layer 822 is inlayed within the first alternative outer conductive plate portion 828-1. Similarly, the second alternative inner conductive plate portion 928-2 is inlayed within the second alternative dielectric layer 922 and within the second alternative outer conductive plate portion 928-1, and the second alternative dielectric layer 922 is inlayed within the second alternative outer conductive plate portion 928-1. As can be understood, in illustrative embodiments, the first and second alternative outer conductive plate portions 828-1 and 928-1 each have a hollow central portion in which the first and second alternative dielectric layers 822 and 922 are respectively formed, and in which the first and second alternative inner conductive plate portions 828-2 and 928-2 are respectively formed.

The first alternative outer conductive plate portion 828-1 is connected (e.g., physically and electrically connected) to a first metal layer through one or more vias 816 and the second alternative inner conductive plate portion 928-2 is connected (e.g., physically and electrically connected) to a second metal layer 914 through a via 916. The first metal layer 814 is at least electrically connected and can be physically connected to a first voltage source, and the second metal layer 914 is at least electrically connected and can be physically connected to a second voltage source.

It is to be appreciated that the hybrid bonding techniques as disclosed herein enable construction of a capacitance structure which provides various advantages over conventional 2-D and 3-D packaging structures and techniques as discussed above. For example, the structure advantageously provides a 3-D compact capacitor structure including parallel non-contacting conductive metallic plates that also function as metallic hybrid bonding pads. The non-contacting metallic plates are separated by one or more layers of dielectric/insulating material. In an illustrative embodiment, one or more of the metallic plates are located within a hollow interior of one or more other parallel metallic plates.

The embodiments advantageously provide for pre-charging to limit in-rush currents at power-up of high voltage direct current (HVDC) circuits. The embodiments further facilitate noise protection by decreasing noise from a power supply at high frequency bands due to circuit switching at high speeds.

Although exemplary embodiments have been described herein with reference to the accompanying figures, it is to be understood that the disclosure is not limited to those precise embodiments, and that various other changes and modifications may be made therein by one skilled in the art without departing from the scope of the appended claims.

What is claimed is:

1. A device, comprising:
a first semiconductor structure disposed on a second semiconductor structure; and
a capacitor structure disposed at an interface portion of the first semiconductor structure and the second semiconductor structure;
wherein the capacitor structure comprises a first conductive plate, at least one dielectric layer inlayed within the first conductive plate and at least a second conductive plate inlayed within the first conductive plate.

2. The device of claim 1, wherein the second conductive plate is further inlayed within the at least one dielectric layer.

3. The device of claim 2, wherein the capacitor structure further comprises at least one additional dielectric layer inlayed within the second conductive plate and at least a third conductive plate inlayed within the at least one additional dielectric layer.

4. The device of claim 1, wherein the first semiconductor structure is hybrid bonded to the second semiconductor structure.

5. The device of claim 1, wherein the capacitor structure comprises one of a circular shape, an oval shape, a square shape and a rectangular shape.

6. The device of claim 1, wherein the capacitor structure is further disposed beyond the interface portion in the first semiconductor structure and in the second semiconductor structure.

7. The device of claim 1, wherein the first conductive plate, the at least one dielectric layer and the second conductive plate are concentric.

8. The device of claim 1, wherein the first conductive plate is electrically connected to a first metal layer and a first voltage source of the first semiconductor structure.

9. The device of claim 8, wherein the second conductive plate is electrically connected to a second metal layer and a second voltage source of the second semiconductor structure.

10. The device of claim 1, wherein the at least one dielectric layer is disposed between the first conductive plate and the second conductive plate and electrically isolates the first conductive plate from the second conductive plate.

11. A device, comprising:
a first semiconductor structure disposed on a second semiconductor structure; and
a capacitor structure comprising a first conductive plate, at least one dielectric layer surrounded by the first conductive plate and at least a second conductive plate surrounded by the first conductive plate and the at least one dielectric layer;
wherein the capacitor structure is disposed in the first semiconductor structure and in the second semiconductor structure.

12. The device of claim 11, wherein the capacitor structure comprises one of a circular shape, an oval shape, a square shape and a rectangular shape.

13. The device of claim 11, wherein the first conductive plate, the at least one dielectric layer and the second conductive plate are concentric.

14. The device of claim 11, wherein the first conductive plate is electrically connected to a first metal layer and a first voltage source of the first semiconductor structure.

15. The device of claim 14, wherein the second conductive plate is electrically connected to a second metal layer and a second voltage source of the second semiconductor structure.

16. The device of claim 11, wherein the at least one dielectric layer is disposed between the first conductive plate and the second conductive plate and electrically isolates the first conductive plate from the second conductive plate.

17. The device of claim 11, wherein the capacitor structure further comprises at least one additional dielectric layer surrounded by the second conductive plate and at least a third conductive plate surrounded by the at least one additional dielectric layer.

18. A device, comprising:
a first semiconductor structure disposed on top of and facing a second semiconductor structure; and
a capacitor structure disposed in the first semiconductor structure and in the second semiconductor structure;
wherein the capacitor structure comprises a first conductive plate disposed around at least one dielectric layer and around at least a second conductive plate, wherein the at least one dielectric layer is disposed around the second conductive plate.

19. The device of claim 18, wherein the first conductive plate, the at least one dielectric layer and the second conductive plate each comprise one of a circular shape, an oval shape, a square shape and a rectangular shape.

20. The device of claim 18, wherein the first conductive plate, the at least one dielectric layer and the second conductive plate are concentric.
